(19) United States
(12) Patent Application Publication
(10) Pub. No.: US 2024/0133018 A1
(43) Pub. Date: Apr. 25, 2024

(54) METAL MASK

(71) Applicant: DARWIN PRECISIONS CORPORATION, Hsinchu County (TW)

(72) Inventors: YunPei Yang, Hsinchu County (TW); Chi-Wei Lin, Hsinchu County (TW)

(21) Appl. No.: 18/125,137

(22) Filed: Mar. 22, 2023

(30) Foreign Application Priority Data
Oct. 20, 2022 (TW) 111140007

(51) Int. Cl. C23C 14/04; C23C 14/24

(52) U.S. Cl. CPC C23C 14/042; C23C 14/24

(57) ABSTRACT

A metal mask includes: a mask body having two opposite first side edges along a first direction and two opposite second side edges along a second direction, and each of the first side edges having a first length. The mask body includes an open slot region, two first fixing regions, and two first clamping regions, where the two first fixing regions are positioned on two opposite sides of the open slot region, respectively, and each of the first clamping regions is positioned between each of the first fixing regions and each of the first side edges. A first gap is formed in each of the first side edges, the first gap has a first opening length in the first direction, and a ratio of the first opening length to the first length being between 0.2 and 0.8. The metal mask may improve the problem of wrinkles.

### FIELD OF THE INVENTION

The present invention relates to a metal mask, and more particularly to a metal mask capable of improving the problem of wrinkles.

### BACKGROUND OF THE INVENTION

Active matrix organic light emitting diode (AMOLED) displays with organic light emitting diodes (OLEDs) as light emitting sources have the advantages of fast display response, ultra-wide viewing angle, ultra-high contrast and saturation, and wide color gamut. In the manufacture procedure for AMOLED panels, organic film forming technology with organic light emitting materials as light emitting sources is required. Vacuum evaporation is the most mature at present, and is also the organic film forming technology used by most of existing small-sized AMOLED products in mass production. During evaporation, fine pitch metal masks (FMMs) need to be used for shielding in film coating to generate pixel graphics, and then organic materials are heated in vacuum to be evaporated and are selectively deposited on substrates via the fine pitch metal masks to form films. The fine pitch metal masks belong to core molds and consumables in the manufacture procedure for AMOLEDs.

However, due to the interference with clamping mechanisms, the fine pitch metal masks may be wrinkled during tensioning or laser welding, such that the fine pitch metal masks cannot be completely attached to the substrates during the evaporation, thereby affecting the evaporation quality.

### SUMMARY OF THE INVENTION

The present invention provides a metal mask, which effectively improves the problem of wrinkles and has the better evaporation quality.

The metal mask provided by the present invention includes: a mask body having two opposite first side edges and two opposite second side edges, the two side edges extending along a first direction, the two second side edges extending along a second direction, each of the first side edges having a first length, the mask body including an open slot region, two first fixing regions, and two first clamping regions arranged between the two first side edges along the second direction, where the two first fixing regions are positioned on two opposite sides of the open slot region, respectively, and each of the first clamping regions is positioned between each of the first fixing regions and each of the first side edges; and a first gap formed in each of the first side edges, the first gap having a first opening length in the first direction, where a ratio of the first opening length to the first length is between 0.2 and 0.8.

In an embodiment of the present invention, there are a plurality of the first gaps, the plurality of the first opening lengths of the plurality of the first gaps positioned in each of the two first side edges are added up to obtain a first length sum, and a ratio of the first length sum to the first length is between 0.2 and 0.8.

In an embodiment of the present invention, the first opening length is greater than 15 mm.

In an embodiment of the present invention, the mask body is rectangular, and the first direction is perpendicular to the second direction.

In an embodiment of the present invention, a plurality of open slots are formed in the open slot region and arranged along the second direction.

In an embodiment of the present invention, the two first clamping regions are suitable for interfering with a clamping mechanism, and the two first fixing regions are suitable for being welded onto a frame.

In an embodiment of the present invention, the first gap includes U-shaped gap, V-shaped gap, rectangular gap, or a combination thereof.

In an embodiment of the present invention, the mask body further includes two second fixing regions and two second clamping regions, wherein the open slot region, the two second fixing regions, and the two second clamping regions are arranged between the two second side edges along the first direction, where the two second fixing regions are positioned on the two opposite sides of the open slot region, respectively, and each of the second clamping regions is positioned between each of the second fixing regions and each of the second side edges.

In an embodiment of the present invention, the metal mask further includes a plurality of second gaps formed in the second side edges, each of the second side edges has a second length, and each of the second gaps has a second opening length in the second direction, where the plurality of the second opening lengths of the plurality of the second gaps positioned in each of the second side edges are added up to obtain a second length sum, and a ratio of the second length sum to the second length is between 0.2 and 0.8.

In an embodiment of the present invention, a single open slot is formed in the open slot region, and the two first fixing regions and the two second fixing regions are connected and arranged around the single open slot.

In the present invention, the ratio of the opening length of the gap in the clamping region to the length of the clamping region is limited, such that the region ratio of the clamping region to the gap does not affect the interference between the clamping region and the clamping mechanism and the quality of tensioning. The present invention may effectively improve the problem of wrinkles and has the better evaporation quality.

### BRIEF DESCRIPTION OF THE DRAWINGS

The present invention will become more readily apparent to those ordinarily skilled in the art after reviewing the following detailed description and accompanying drawings, in which:

FIG. 1 is a schematic structural diagram of a metal mask according to an embodiment of the present invention;

FIG. 2A and FIG. 2B show a schematic top view and a schematic side view of a metal mask according to an embodiment of the present invention in application, respectively;

FIG. 3A to FIG. 3C show schematic diagrams of different embodiments of a metal mask according to the present invention, respectively;

FIG. 4 is a schematic structural diagram of a metal mask according to another embodiment of the present invention; and

FIG. 5 is a schematic structural diagram of a metal mask according to another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

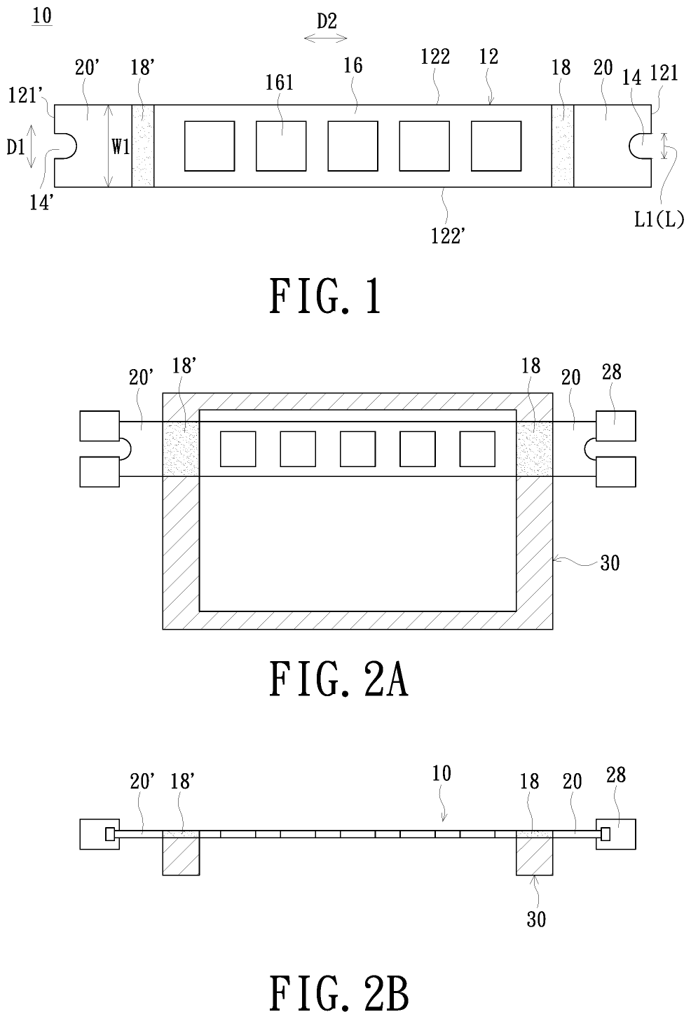

FIG. 1 is a schematic structural diagram of a metal mask according to an embodiment of the present invention. As shown in FIG. 1, the metal mask 10 includes a mask body 12 and a plurality of first gaps 14, 14′ formed in the mask body 12. In an embodiment, the mask body 12 is, for example, rectangular, and has two opposite first side edges 121, 121′ and two opposite second side edges 122, 122′. The first side edges 121, 121′ extend along a first direction D1, and the two second side edges 122, 122′ extend along a second direction D2. The first direction D1 is, for example, perpendicular to the second direction D2. Each of the first side edges 121, 121′ has a first length W1, and the first length W1 is, for example, a shortest distance between the two opposite second side edges 122 and 122′.

Continuing with the above description, the mask body 12 includes an open slot region 16, two first fixing regions 18, 18′, and two first clamping regions 20, 20′, and the open slot region 16, the two first fixing regions 18, 18′, and the two first clamping regions 20, 20′ are arranged between the two first side edges 121, 121′ along the second direction D2, where the two first fixing regions 18, 18′ are positioned on two opposite sides of the open slot region 16, respectively, and the first clamping region 20/20′ is positioned between the first fixing region 18/18′ and the first side edge 121/121′. In addition, the above first length W1 may be, for example, the shortest distance between the two opposite second side edges 122 and 122′ of the first clamping regions 20, 20′.

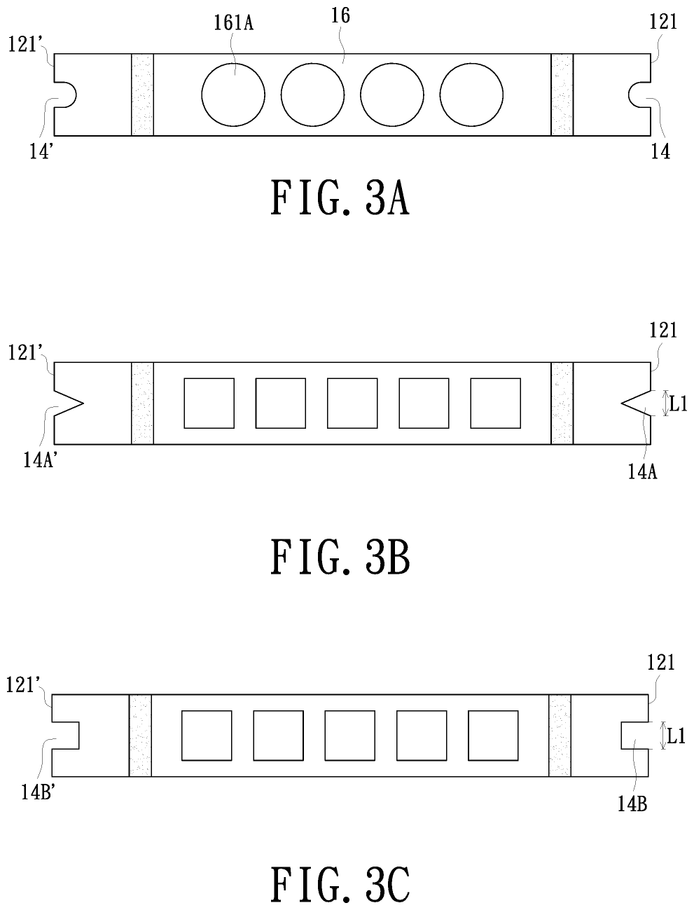

Herein, a plurality of open slots 161 are formed in the open slot region 16, and the plurality of open slots 161 are arranged between the two first fixing regions 18, 18′ along the second direction D2. As shown in FIG. 1, a shape of the open slot 161 is, for example, a rectangle, but not limited to this. In other embodiments, as shown in subsequent FIG. 3A, a shape of an open slot 161A is, for example, a circle.

Continuing with the above description, the first gap 14/14′ is formed in each first side edge 121/121′, and the first gap 14/14′ has a first opening length L1 in the first direction D1. In an embodiment, the first opening length L1 is greater than 15 mm. On the premise that only a single first gap 14/14′ is formed in each of the two first side edges 121/121′, the first opening length L1 may serve as a first length sum L of the first gap 14/14′ of the single first side edge 121/121′, where a ratio of the first length sum L to the first length W1 is between 0.2 and 0.8, that is, 0.2<L/W<0.8, or in this embodiment, 0.2<L1/W<0.8. In addition, as shown in FIG. 1, the first gap 14/14′ is, for example, a U-shaped gap formed in the first side edge 121/121′.

FIG. 2A and FIG. 2B show a schematic top view and a schematic side view of a metal mask according to an embodiment of the present invention in application, respectively. As shown in FIG. 2A and FIG. 2B, the two first clamping regions 20, 20′ are suitable for interfering with a clamping mechanism 28, so as to tension the metal mask 10 on a frame 30, and the two first fixing regions 18, 18′ are suitable for being welded onto the frame 30, such that during evaporation, an organic material is heated in vacuum to be evaporated and is deposited on a substrate (not shown in figure) via the metal mask 10 to form a film.

FIG. 3A to FIG. 3C show schematic diagrams of different embodiments of a metal mask according to the present invention, respectively. As shown in FIG. 3A, the first gap 14/14′ is, for example, the U-shaped gap formed in the first side edge 121/121′, and a plurality of circular open slots 161A are formed in the open slot region 16; and the first gap 14/14′ is not limited to the U-shaped gap, and may be a V-shaped gap, a rectangular gap, or a combination thereof. As shown in FIG. 3B, a first gap 14A/14A′ is, for example, the V-shaped gap formed in the first side edge 121/121′, and the first gap 14A/14A′ has the first opening length L1. As shown in FIG. 3C, a first gap 14B/14B′ is, for example, the rectangular gap formed in the first side edge 121/121′, and the first gap 14B/14B′ has the first opening length L1.

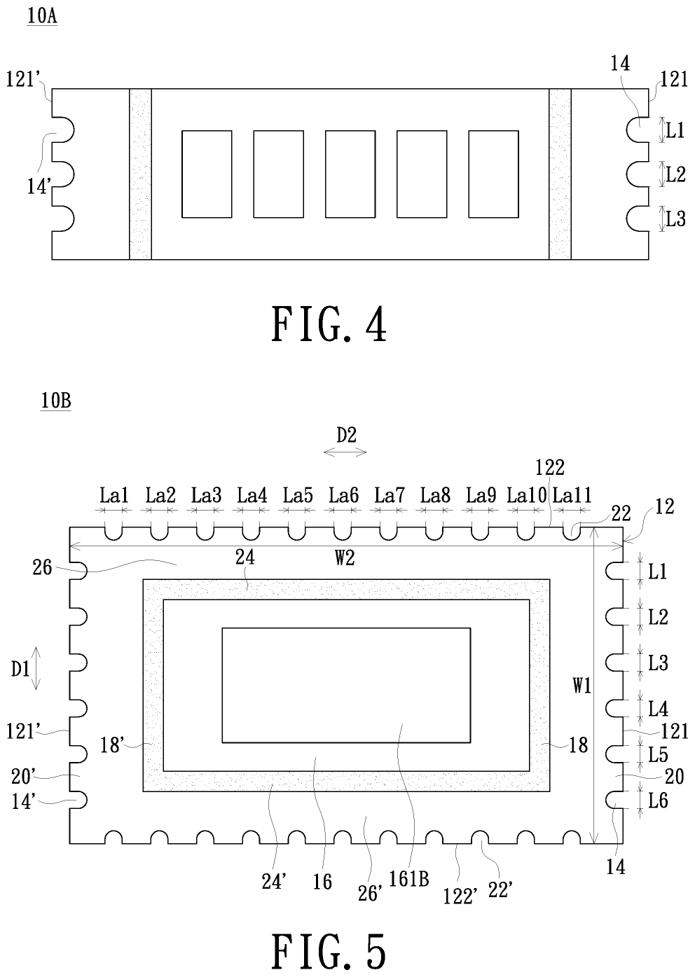

In the above embodiment, by taking FIG. 1 as an example, the first side edge 121/121′ is provided with only a single first gap 14/14′, but is not limited to this. FIG. 4 is a schematic structural diagram of a metal mask according to another embodiment of the present invention. A main difference between the metal mask 10A shown in FIG. 4 and the metal mask 10 shown in FIG. 1 is that the first side edge 121/121′ of the metal mask 10A is provided with a plurality of first gaps 14/14′. In an embodiment, by taking an example where the same first side edge 121 has three first gaps 14, the three first gaps 14 have a first opening length L1, a first opening length L2, and a first opening length L3, respectively; the first opening length L1, the first opening length L2, and the first opening length L3 are added up to obtain a first length sum L, namely, L=L1+L2+L3; and a ratio of the first length sum L to the first length W1 is between 0.2 and 0.8, namely, 0.2<L/W1<0.8, where each of the first opening length L1, the first opening length L2, and the first opening length L3 is greater than 15 mm.

In the metal mask according to the embodiment of the present invention, the ratio of the first opening length of the single first gap to the first length of the first clamping region is limited, or the ratio of the sum of the plurality of first opening lengths of the same first side edge to the first length of the first clamping region is limited, such that the region ratio of the first clamping region to the first gap does not affect the interference between the first clamping region and the clamping mechanism and the quality of tensioning. Specifically, because the ratio between the first opening length of the first gap and the first length of the first clamping region is limited, it is avoided that the metal mask is wrinkled due to falloff or uneven tension of the metal mask during tensioning of the metal mask because a clamping area of the clamping mechanism is too small due to the too large first gap and the too small clamping region on two sides of the first gap; and it is avoided that the clamping region interferes with the clamping mechanism due to the too small first gap. Therefore, the metal mask according to the embodiment of the present invention effectively improves the problem of wrinkles, may be completely attached to the substrate, and has the better evaporation quality.

FIG. 5 is a schematic structural diagram of a metal mask according to another embodiment of the present invention. As shown in FIG. 5, the metal mask 10B includes the mask body 12, and the plurality of first gaps 14, 14′ and a plurality of second gaps 22, 22′ formed around the mask body 12. In an embodiment, the mask body 12 is, for example, rectangular, and has the two opposite first side edges 121, 121′ and the two opposite second side edges 122, 122′. The first side edges 121, 121′ extend along the first direction D1, and the two second side edges 122, 122′ extend along the second direction D2. The first direction D1 is, for example, perpendicular to the second direction D2. The first side edge 121/121′ has the first length W1, and the first length W1 is, for example, the shortest distance between the two opposite second side edges 122, 122′. The second side edge 122/122′ has a second length W2, and the second length W2 is, for example, a shortest distance between the two opposite first side edges 121 and 121′.

Continuing with the above description, the mask body 12 includes the open slot region 16, the two first fixing regions 18, 18′, two second fixing regions 24, 24′, the two first clamping regions 20, 20′, and two second clamping regions 26, 26′. The open slot region 16, the two first fixing regions 18, 18′, and the two first clamping regions 20, 20′ are arranged between the two first side edges 121, 121′ along the second direction D2, where the two first fixing regions 18, 18′ are positioned on the two opposite sides of the open slot region 16, respectively, and the first clamping region 20/20′ is positioned between the first fixing region 18/18′ and the first side edge 121/121′. In addition, the open slot region 16, the two second fixing regions 24, 24′, and the two second clamping regions 26, 26′ are arranged between the two second side edges 122, 122′ along the first direction D1, where the two second fixing regions 24, 24′ are positioned on the two opposite sides of the open slot region 16, respectively, and the second clamping regions 26, 26′ are positioned between the second fixing regions 24, 24′ and the second side edges 122, 122′. Specifically, in an embodiment, a single open slot 161B is formed in the open slot region 16; the two first fixing regions 18, 18′, and the two second fixing regions 24, 24′ are connected and arranged around the single open slot 161B; and the two first clamping regions 20, 20′ and the two second clamping regions 26, 26′ are connected and arranged around the first fixing regions 18, 18′ and the second fixing regions 24, 24′.

In addition, a plurality of first gaps 14/14′ are formed in the first side edge 121/121′, and a plurality of second gaps 22/22′ are formed in the second side edge 122/122′. Herein, by taking the plurality of first gaps 14 and the plurality of second gaps 22 as an example for description, the plurality of first gaps 14 have first opening length L1, first opening length L2, first opening length L3, first opening length L4, first opening length L5 and first opening length L6 in the first direction D1, respectively; the first opening lengths L1, L2, L3, L4, L5, and L6 of the plurality of first gaps 14 are added up to obtain a first length sum L; the plurality of second gaps 22 have second opening length La1, second opening length La2, second opening length La3, second opening length La4, second opening length La5, second opening length La6, second opening length La7, second opening length La8, second opening length La9, second opening length La10 and second opening length La11 in the second direction D2, respectively; and the second opening lengths La1, La2, La3, La4, La5, La6, La7, La8, La9, La10, and La11 of the plurality of second gaps 22 are added up to obtain a second length sum La. Herein, a ratio of the first length sum L to the first length W1 is between 0.2 and 0.8, and a ratio of the second length sum La to the second length W2 is between 0.2 and 0.8.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A metal mask, comprising:
a mask body having two opposite first side edges and two opposite second side edges, the two side edges extending along a first direction, the two second side edges extending along a second direction, each of the two first side edges having a first length, the mask body comprising an open slot region, two first fixing regions, and two first clamping regions arranged between the two first side edges along the second direction, wherein the two first fixing regions are positioned on two opposite sides of the open slot region, respectively, and each of the two first clamping regions is positioned between each of the two first fixing regions and each of the two first side edges; and
at least one first gap formed in each of the two first side edges, each of the at least one first gap having a first opening length in the first direction, wherein a ratio of the first opening length to the first length is between 0.2 and 0.8.

2. The metal mask according to claim 1, wherein a number of the at least one first gap in each of the two first side edges is plural, the plurality of the first opening lengths of the plurality of first gaps positioned in each of the two first side edges are added up to obtain a first length sum, and a ratio of the first length sum to the first length is between 0.2 and 0.8.

3. The metal mask according to claim 1, wherein the first opening length is greater than 15 mm.

4. The metal mask according to claim 1, wherein the mask body is rectangular, and the first direction is perpendicular to the second direction.

5. The metal mask according to claim 1, wherein a plurality of open slots are formed in the open slot region and arranged along the second direction.

6. The metal mask according to claim 1, wherein the two first clamping regions are suitable for interfering with a clamping mechanism, and the two first fixing regions are suitable for being welded onto a frame.

7. The metal mask according to claim 1, wherein the at least one first gap comprises U-shaped gap, V-shaped gap, rectangular gap, or a combination thereof.

8. The metal mask according to claim 1, wherein the mask body further comprises two second fixing regions and two second clamping regions, wherein the open slot region, the two second fixing regions, and the two second clamping regions are arranged between the two second side edges along the first direction, the two second fixing regions are positioned on the two opposite sides of the open slot region, respectively, and each of the two second clamping regions is positioned between each of the two second fixing regions and each of the two second side edges.

9. The metal mask according to claim 8, further comprising a plurality of second gaps formed in the two second side edges, each of the two second side edges having a second length, each of the plurality of the second gaps having a second opening length in the second direction, wherein the plurality of the second opening lengths of the plurality of the second gaps positioned in each of the two second side edges are added up to obtain a second length sum, and a ratio of the second length sum to the second length is between 0.2 and 0.8.

10. The metal mask according to claim 8, wherein a single open slot is formed in the open slot region, and the two first fixing regions and the two second fixing regions are connected and arranged around the single open slot.
